(19) United States
(12) Patent Application Publication
(10) Pub. No.: US 2022/0005890 A1
(43) Pub. Date: Jan. 6, 2022

(54) AN ARRAY SUBSTRATE, A METHOD FOR MANUFACTURING THE SAME, AND A DISPLAY DEVICE

(71) Applicant: Wuhan China Star Optoelectronics Semiconductor Display Technology Co., Ltd., Wuhan, Hubei (CN)

(72) Inventor: Bo YAN, Wuhan (CN)

(21) Appl. No.: 16/623,065

(22) PCT Filed: Nov. 6, 2019
(86) PCT No.: PCT/CN2019/115895

§ 371 Date: Dec. 16, 2019

(30) Foreign Application Priority Data
Aug. 20, 2019 (CN) 201910767455.9

(51) Int. Cl. H01L 27/32; H01L 51/56

(52) U.S. Cl. CPC H01L 27/3234; H01L 27/3246; H01L 2227/323; H01L 27/3248; H01L 51/56

(57) ABSTRACT

The application discloses an array substrate, a method for manufacturing the array substrate and a display device. The array substrate includes a base substrate, a thin-film transistor layer and an anode layer formed on the base substrate. The anode layer includes first anodes in a display area of the base substrate and being connected with thin-film transistors of the thin-film transistor layer, and second anodes in a camera area of the base substrate and being connected with the first anodes within a preset range of the camera area by a metal connection layer.

### BACKGROUND OF THE INVENTION

### 1. Field of the Invention

The present invention relates to a display technical field, and more particularly to an array substrate, a method for manufacturing the same, and a display device.

### 2. Description of the Prior Art

Organic light-emitting diode (OLED) devices are considered as a new generation of display technology because of their flexible display characteristics. They have broad application prospects in smart phones, tablets and other display devices. In the prior art, a front camera can be hidden under the display device, so that an area of the display device corresponding to the camera can display normally, so as to increase the screen proportion of the display device.

### BRIEF SUMMARY OF THE INVENTION

### Technical Problem

The mode of hiding the camera under the display device will make the area of the array substrate corresponding to the camera have a large number of opaque metal lines, such as an amorphous silicon (A-Si) layer, a gate electrode (GE) layer and a source/drain (SD) layer, which will result in the low light transmittance of the array substrate corresponding to the camera and affect the imaging effect of the front camera.

### Technical Solutions

The application provides an array substrate, a method for manufacturing the array substrate, and a display device, the purpose of which is to improve the structure of the array substrate, improve the light transmittance of a camera area of the array substrate corresponding to a camera, and improve the imaging effect of the camera, while hiding the camera beneath the array substrate.

The application provides an array substrate being applied in a display device with a camera. The array substrate includes:

a base substrate, having a display area and a camera area corresponding to the camera;

a thin-film transistor layer, being formed on the base substrate; the thin-film transistor layer including thin-film transistors in the display area and multiple insulation layers in the camera area;

a planarization layer, being formed on the thin-film transistor layer;

an anode layer, being formed on the planarization layer; the anode layer including first anodes in the display area and being connected with the thin-film transistors, and second anodes in the camera area; and

a metal connection layer, connecting the second anodes and the first anodes within a preset range of the camera area.

In some embodiments of the application, the first anode and the second anode corresponding to the same color sub-pixel are connected together by the metal connection layer.

In some embodiments of the application, the first anodes and the second anodes are arranged on the planarization layer in array; the first anode and the second anode on the same line or the same column are connected together through the metal connection layer.

In some embodiments of the application, the metal connection layer is formed on the planarization layer.

In some embodiments of the application, the thin-film transistor includes a gate layer, an active layer and a source-drain layer; the metal connection layer is disposed in the same layer as the gate layer, the active layer and the source-drain layer.

In some embodiments of the application, the metal connection layer includes multiple sub-metal layers arranged in turn along an up and down direction; the insulation layers or the planarization layer are formed between adjacent two sub-metal layers; the first anode and the second anode corresponding to the same color sub-pixel are connected together by the same sub-metal layer.

In some embodiments of the application, the insulation layers includes a gate insulation layer and an inter-level dielectric layer; the number of the sub-metal layers is three; the three sub-metal layers are formed on the gate insulation layer, the inter-level dielectric layer and the planarization layer, respectively.

In some embodiments of the application, a pixel defined layer is formed on the anode layer, and includes sub-pixel openings exposing the first and second anodes and accommodating an organic electroluminescent layer.

In some embodiments of the application, the array substrate further includes a buffer layer, which is located between the base substrate and the thin-film transistor layer.

The application further provides a method for manufacturing an array substrate, including:

providing a base substrate, which has a display area and a camera area corresponding to a camera;

forming a thin-film transistor layer on the base substrate; the thin-film transistor layer including multiple thin-film transistors in the display area and multiple insulation layers in the camera area;

forming a planarization layer on the thin-film transistor layer;

form an anode layer on the planarization layer; the anode layer including first anodes located in the display area and connected with the thin-film transistors, and second anodes located in the camera area; and

form a metal connection layer on the insulation layers and/or the planarization layer; the metal connection layer being used to connect the second anodes and the first anodes within a preset range of the camera area.

In some embodiments of the application, the method further includes:

forming a pixel defined layer on the anode layer; the pixel defined layer including sub-pixel openings exposing the first and second anodes;

forming an organic electroluminescent layer on the pixel defined layer;

the organic electroluminescent layer including a hole transport layer, an emitting layer, an electron transport layer; and

forming a cathode layer on the organic electroluminescent layer.

The application further provides a display device, including a camera and an array substrate. The array substrate comprises:

a base substrate, having a display area and a camera area corresponding to the camera;

a thin-film transistor layer, being formed on the base substrate; the thin-film transistor layer including thin-film transistors in the display area and multiple insulation layers in the camera area;

a planarization layer, being formed on the thin-film transistor layer;

an anode layer, being formed on the planarization layer; the anode layer including first anodes in the display area and being connected with the thin-film transistors, and second anodes in the camera area; and

a metal connection layer, connecting the second anodes and the first anodes within a preset range of the camera area.

In some embodiments of the application, the first anode and the second anode corresponding to the same color sub-pixel are connected together by the metal connection layer.

In some embodiments of the application, the first anodes and the second anodes are arranged on the planarization layer in array; the first anode and the second anode on the same line or the same column are connected together through the metal connection layer.

In some embodiments of the application, the metal connection layer is formed on the planarization layer.

In some embodiments of the application, the thin-film transistor includes a gate layer, an active layer and a source-drain layer; the metal connection layer is disposed in the same layer as the gate layer, the active layer and the source-drain layer.

In some embodiments of the application, the metal connection layer includes multiple sub-metal layers arranged in turn along an up and down direction; the insulation layers or the planarization layer are formed between adjacent two sub-metal layers; the first anode and the second anode corresponding to the same color sub-pixel are connected together by the same sub-metal layer.

In some embodiments of the application, the insulation layers includes a gate insulation layer and an inter-level dielectric layer; the number of the sub-metal layers is three; the three sub-metal layers are formed on the gate insulation layer, the inter-level dielectric layer and the planarization layer, respectively.

In some embodiments of the application, a pixel defined layer is formed on the anode layer, and includes sub-pixel openings exposing the first and second anodes and accommodating an organic electroluminescent layer.

In some embodiments of the application, the array substrate further includes a buffer layer, which is located between the base substrate and the thin-film transistor layer.

### Beneficial Effect

The array substrate of the application removes the thin-film transistors and the signal lines in the camera area corresponding to the camera, so that greatly improving the light transmittance of the area and the image quality of the camera. Moreover, the second anodes can be connected to the first anodes within the preset range of the camera area. When a voltage is applied to the thin-film transistors within the preset range of the camera area, the pixel units in the camera area can display the color to hide the camera under the array substrate.

### BRIEF DESCRIPTION OF THE DRAWINGS

For more clearly illustrating the technical scheme in the embodiments of the present application, the following text will briefly introduce the accompanying drawings used in the embodiments. It is obvious that the accompanying drawings in the following description are only some embodiments of the present application. For the technical personnel of the field, other drawings can also be obtained from these drawings without paying creative work.

FIG. 1 is a structure schematic view of one embodiment of a display device provided by the present application;

FIG. 2 is a cross section view of one embodiment of an array substrate provided by the present application;

FIG. 3 is a connection diagram of a first anode and a second anode of the array substrate provided in the present application;

FIG. 4 is a cross section view of another embodiment of the array substrate provided by the present invention; and

FIG. 5 is a flow chart of one embodiment of a method for manufacturing the array substrate provided by the present invention.

display device 10; array substrate 11; base substrate 111; camera area 1111; display area 1112; buffer layer 112; thin-film transistor layer 113; gate layer 1131; active layer 1132; source-drain layer 1133; gate insulation layer 1134; inter-level dielectric layer 1135; planarization layer 114; anode layer 115; first anode 1151; second anode 1152; metal connection layer 116; metal connection layer 116a; sub-metal layer 1161; pixel defined layer 117; organic electroluminescent layer 118; cathode layer 119; packaging layer 120.

### DETAILED DESCRIPTION OF THE PREFERRED EMBODIMENTS

The following text will clearly and completely describe the technical scheme of the present application with reference to the accompanying drawings. Obviously, the embodiments described are only part of the embodiments of the present application, not all of them. Based on the embodiments of the present application, all other embodiments acquired by a skilled person in the art without creative work can fall within the protection scope of the present application.

In the description of this application, it is to be understood that the terms, such as “center”, “longitudinal”, “horizontal”, “length”, “width”, “thickness”, “up”, “down”, “front”, “back”, “left”, “right”, “vertical”, “horizontal”, “top”, “bottom”, “inside” and “outside” are used to represent orientation relations or position relations shown in the drawings. These terms are intended to facilitate the description of this application and simplify the description, rather than to indicate or imply that the described device or element must have a specific orientation, be constructed and operated in a specific orientation, and therefore they cannot be used as a limitation of this application. Moreover, the terms, such as “first” and “second” are used only for descriptive purposes and cannot be understood as indicating or implying relative importance or implying the number of technical features indicated. Therefore, the features defined as “first” and “second” can explicitly or implicitly include one or more of the said features. In the description of this application, the term “multiple” means two or more unless otherwise specified.

In this application, the term “illustrative” is used to denote “used as an example, illustration or explain”. Any embodiments described as “exemplary” in this application may not necessarily be interpreted as preferred or more advantageous than other embodiments. In order to enable any person skilled in the field to implement and use this application, the following description is given. Details are listed for the purposes of explanation in the following description. It should be understood that those of ordinary skill in the field may recognize that this application can also be implemented without using these specific details. In other examples, well-known structures and processes will not be elaborated in detail to avoid unnecessary details that obscure the description of this application. Therefore, the present application is not intended to be limited to the embodiments shown, but to be consistent with the broadest scope of the principles and characteristics disclosed in the present application.

This application provides an array substrate, which is mainly used in a display device with a camera. Details are given below.

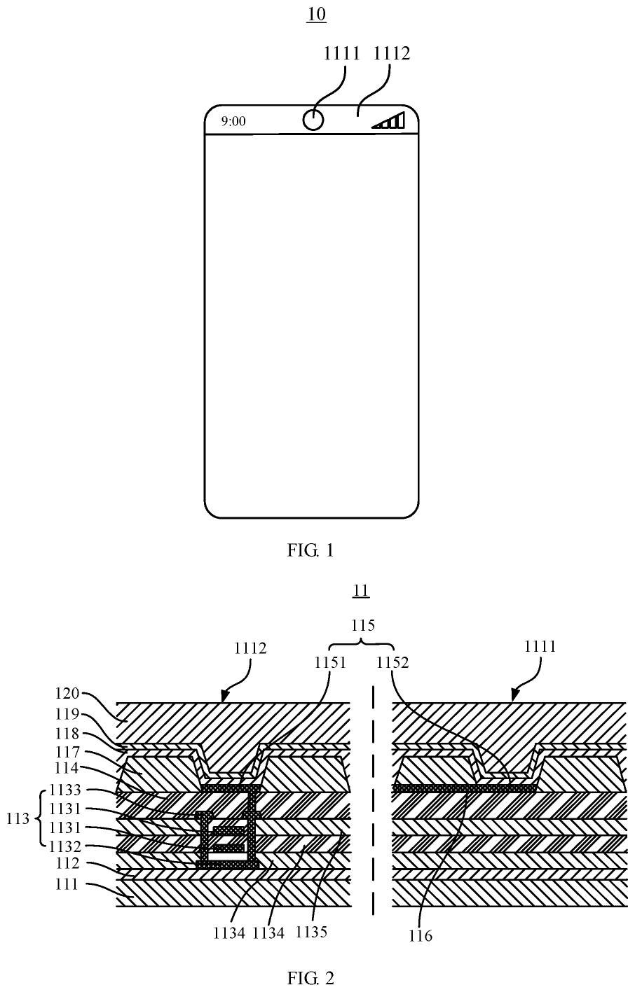

Please refer to FIGS. 1 and 2, the array substrate 11 includes a base substrate 111, and a thin-film transistor (TFT) layer 113, a planarization (PLN) layer 114, an anode (ANO) layer 115 and so on, which are formed on the base substrate 111.

Wherein, the base substrate 111 has a display area 1112 and a camera area 1111. The display area 1112 of the base substrate 111 is corresponding to an area of a display device 10 used to display a picture. The camera area 1111 of the base substrate 111 is corresponding to a camera (not shown in drawing) of the display device 10, so that the light outside the display device 10 can pass through the camera area and enter into the camera.

Optionally, the base substrate 111 is a transparent substrate, which can be a transparent glass substrate, or a transparent flexible substrate made of polyimide (PI), polyethylene terephthalate (PET), cyclolefin copolymer (COC), or polyethersulfone resin (PES), etc.

The thin-film transistor layer 113 is formed on the base substrate 111. The thin-film transistor layer 113 includes thin-film transistors in the display area 1112 and multiple insulation layers in the camera area 1111.

The thin-film transistor is one type of field effect transistors. Each thin-film transistor includes an active layer 1132, a gate layer 1131 and a source-drain layer 1133. The source-drain layer 1133 includes a source and a drain, which are contacted on both sides of the active layer 1132. The gate layer 1131 and the active layer 1132 are separated by the insulation layers, and the gate layer 1131 and the source-drain layer 1133 are also separated by the insulation layers.

Optionally, the active layer 1132 can be made of amorphous silicon, low temperature polycrystalline silicon and other semiconductor materials.

Optionally, there are two gate layers 1131 arranged on the active layer 1132 in turn along an up and down direction. There are gate insulation (GI) layers 1134, which are disposed between the gate layer 1131 and the active layer 1132, and between the two gate layers 1131. The gate insulation layers 1134 are insulation layers for being used to separate the gate layer 1131 and the active layer 1132, and separate the two gate layers 1131.

There is an inter-level dielectric (ILD) layer 1135 and the source-drain layer 1133 arranged on the gate layer 1131 in turn. The inter-level dielectric layer 1135 is an insulation layer for being used to separate the source-drain layer 1133 and the gate layer 1131. A source electrode and a drain electrode of the source-drain layer 1133 pass through the inter-level dielectric layer 1135 and two gate insulation layers 1134, and contact with two sides of the active layer 1132.

It should be noted that, the thin-film transistor of the thin-film transistor layer 113 located in the display area 1112 of the base substrate 111 is composed of the active layer 1132, the two gate insulation layers 1134, the two gate layers 1131, the inter-level dielectric layer 1135 and the source-drain layer 1133, etc. The multiple insulation layers of the thin-film transistor layer 113 located in the camera area 1111 of the base substrate 111 may includes the gate insulation layers 1134 and the inter-level dielectric layer 1135, etc.

The planarization layer 114 is formed on the thin-film transistor layer 113 for flattening the thin-film transistor layer 113. Wherein, the planarization layer 114 is made of silicon oxide, silicon nitride or organic resin, etc.

The anode layer 115 is formed on the planarization layer 114. The anode layer 115 includes first anodes 1151 located in the display area 1112 and connected to the thin-film transistor, and second anodes 1152 located in the camera area 1111. Specifically, each first anode 1151 of the anode layer 115 passes through the planarization layer 114 to contact with the drain electrode of the source-drain layer 1133, so that the first anode of the anode layer 115 can provide electron holes. Wherein, the anode layer 115 can be made of indium tin oxide and other metal oxides.

In some embodiments, as shown in FIG. 2, there is a buffer layer 112 formed between the base substrate 111 and the thin-film transistor layer 113. The buffer layer 112 is used to buffer the stress produced when the array substrate 11 is bent, thereby stabilizing the state of the display device 10 when the display device 10 is bent. Wherein, the buffer layer 112 is formed in the display area 1112 and the camera area 1111 of the base substrate 111. The buffer layer 112 is made of an organic insulation material.

In some embodiments, as shown in FIG. 2, the array substrate 11 further includes a metal connection layer 116. Each second anode 1152 can be connected to one first anode 1151 within a preset range of the camera area 1111 by the metal connection layer 116. Therefore, when a voltage is applied to the thin-film transistor within the preset range of the camera area 1111, pixel units in the camera area 1111 can display the color to hide the camera under the array substrate 11. Moreover, because the camera area 1111 of the base substrate 111 is not provided with thin-film transistors and signal lines, a light transmittance of the camera area 1111 is increased, and more external light can enter into the camera through the camera area 1111 of the base substrate 111, thereby improving the image effect of the camera.

Wherein, the preset range of the camera area 1111 can be a range corresponding to the first anodes 1151 near an edge of the camera area 1111, and can be determined according to the connection mode of the first anodes 1151 and the second anodes 1152.

In some embodiments, the first and second anodes 1151, 1152 corresponding to the same color sub-pixels can be connected through the metal connection layer 116.

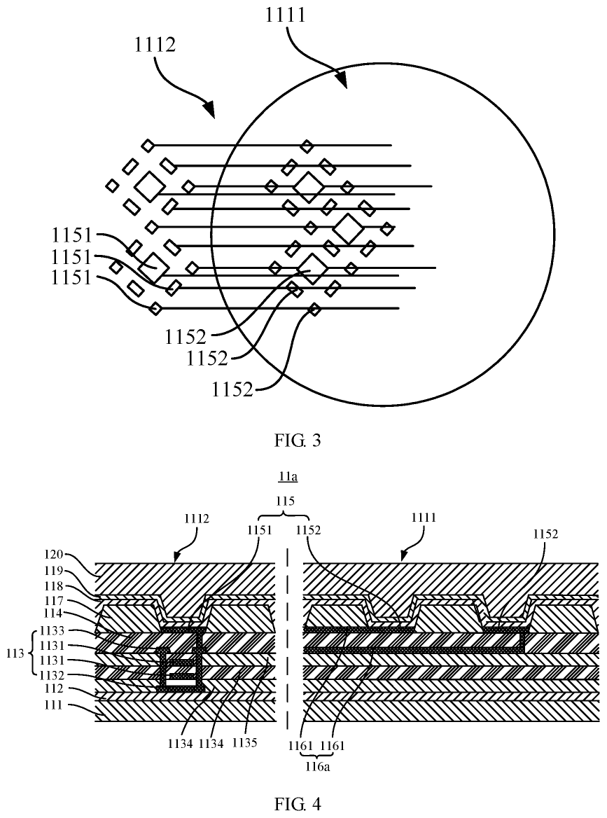

Specifically, referring to FIG. 3, each pixel unit includes a red sub-pixel, a green sub-pixel and a blue sub-pixel. In the display area 1112 of the base substrate 111, the red, green and blue sub-pixels are corresponding to the different first anodes 1151, respectively; and in the camera area 1111 of the base substrate 111, the red, green and blue sub-pixels are corresponding to the different second anodes 1152, respectively. The first and second anodes 1151, 1152 (represented by small squares in FIG. 3) corresponding to the red sub-pixel are connected together by the metal connection layer 116. The first and second anodes 1151, 1152 (represented by rectangles in FIG. 3) corresponding to the green sub-pixel are connected together by the metal connection layer 116. The first and second anodes 1151, 1152 (represented by large squares in FIG. 3) corresponding to the blue sub-pixel are connected together by the metal connection layer 116.

Understandably, because the first and second anodes 1151, 1152 corresponding to the same color sub-pixel are connected together by the metal connection layer 116, the color displayed by the pixel units in the camera area 1111 is consistent with the color displayed by the pixel units in the preset range of the camera area 1111. Thus, it is more convenient to control the color displayed by the pixel units in the camera area 1111.

Of course, the second anodes 1152 corresponding to the different color sub-pixels can be connected to the first anodes corresponding to the same color sub-pixels by the metal connection layer 116. For example, three second anodes 1152 corresponding to the red, green and blue sub-pixels are connected to the first anodes 1151 corresponding to the red sub-pixels by the metal connection layer 116. When a voltage is applied to the first anodes 1151 corresponding to the red sub-pixels, the three second anodes 1152 corresponding to the red, green and blue sub-pixels have the same voltage. Therefore, the red, green and blue sub-pixels of the pixel units in the camera area 1111 have the same brightness, so that the pixel units in the camera area 1111 can display pure white to cover the camera under the array substrate 11.

Or, the first anode 1151 and the second anode 1152 corresponding to the different color sub-pixels can be connected together through the metal connection layer 116. For example, the first anode 1151 corresponding to the red sub-pixel and the second anode 1152 corresponding to the green sub-pixel are connected together through the metal connection layer 116; the first anode 1151 corresponding to the green sub-pixel and the second anode 1152 corresponding to the blue sub-pixel are connected together through the metal connection layer 116; and the first anode 1151 corresponding to the blue sub-pixel and the second anode 1152 corresponding to the red sub-pixel are connected together through the metal connection layer 116.

When the same voltage is applied to the first anodes 1151 within the preset range of the camera area 1111, the second anodes 1152 corresponding to the different color sub-pixels have the same voltage, so that the pixel units within the preset range of the camera area 1111 and the pixel units in the camera area 1111 will display pure white. Of course, when different voltages are applied to the first anodes 1151 within the preset range of the camera area 1111, the color displayed by the pixel units within the preset range of the camera area 1111 and the color displayed by the pixel units in the camera area 1111 are different.

In some embodiments, the first anodes 1151 and the second anodes 1152 are arranged on the planarization layer 114 in array. Referring to FIG. 3, the first anode 1151 and the second anode 1152 on the same line are connected together through the metal connection layer 116, so that the structure of the anode layer 115 on the planarization layer 114 is simpler and more convenient to be formed.

Wherein, the first anode 1151 and the second anode 1152 being on the same line and corresponding to the same color sub-pixel are connected together through the metal connection layer 116; or the first anode 1151 and the second anode 1152 being on the same line and corresponding to the different color sub-pixels are connected together through the metal connection layer 116. Of course, the former can make the color displayed by the pixel unit in the preset range of the camera area 1111 be consistent with the color displayed by the pixel unit in the camera area 1111.

Or, the first anode 1151 and the second anode 1152 on the same column are connected together through the metal connection layer 116, so that the structure of the anode layer 115 on the planarization layer 114 is simpler and more convenient to be formed. It is not repeated here.

In some embodiments, as shown in FIG. 2, the metal connection layer 116 can be formed on the planarization layer 114. Specifically, the metal connection layer 116 can be formed on the planarization layer 114 after the formation of the planarization layer 114, and the structure of the metal connection layer 116 can be determined according to the connection mode of the first anode 1151 and the second anode 1152.

For example, when the first anode 1151 and the second anode 1152 being on the same line and corresponding to the same color sub-pixel are connected through the metal connection layer 116, multiple horizontal extension metal connection lines need to be formed on the planarization layer 114. Therefore, the first anode 1151 and the second anode 1152 being on the same line and corresponding to the same color sub-pixel are connected by the same metal connection line.

Of course, the metal connection layer 116 can also be arranged in the same layer as the gate layer 1131, the active layer 1132 or the source-drain layer 1133 of the thin-film transistor layer 1131.

Taking the metal connection layer 116 and the source-drain layer 1133 in the same layer as an example, the metal connection layer 116 may be formed on the inter-level dielectric layer 1135. The second anode 1152 can pass through the planarization layer 114 to be connected to the metal connection layer 116 on the inter-level dielectric layer 1135. Moreover, the first anode 1151 can also pass through the planarization layer 114 to be connected to the metal connection layer 116 on the inter-level dielectric layer 1135. Or, the metal connection layer 116 can contact with the drain electrode of the source-drain layer 1133, so that the metal connection layer 116 can be connected with the first anode 1151.

In other embodiments, referring to FIG. 4, the metal connection layer 116a of the array substrate 11a can include multiple sub-metal layers arranged in turn along the up and down direction. There forms the insulation layer or the planarization layer 114 between two adjacent sub-metal layers 1161, for separating the two adjacent sub-metal layers 1161. Wherein, each sub-metal layer 1161 can correspondingly connect one or more second anode 1152 with one or more first anode 1151.

Understandably, the metal connection layer 116a is divided into multiple sub-metal layers 1161 which distribute sequentially along the up and down direction, thereby reducing the area occupied by the metal connection layer 116a and improving the light transmittance of the camera area 1111 of the array substrate 11.

It should be noted that the insulation layer can include the gate insulation layer 1134, the inter-level dielectric layer 1135, etc. That is depending on the specific structure of the array substrate 11a. Moreover, the multiple sub-metal layers 1161 can be set in the same layer as one or more of the active layer 1132, two gate layers 1131, the source-drain layer 1133 and the anode layer 115, depending on the number of the sub-metal layers 1161 and the specific structure of the array substrate 11.

Optionally, the first anode 1151 and the second anode 1152 corresponding to the same color sub-pixel can be connected through the same sub-metal layer 1161, thereby simplifying the structure of the metal connection layer 116. Specifically, for example, the first anode 1151 and the second anode 1152 corresponding to the red sub-pixel are connected together through the same sub-metal layer 1161.

Of course, the first anode 1151 and the second anode 1152 corresponding to the different color sub-pixels may be connected through the same sub-metal layer 1161. It can be determined by the connection mode of the first anode 1151 and the second anode 1152.

In some embodiments, the number of the sub-metal layers 1161 is three. The three sub-metal layers 1161 are formed on the gate insulation layer 1134, the inter-level dielectric layer 1135 and the planarization layer 114 respectively, to ensure that the second anodes 1152 corresponding to the three color sub-pixels in the camera area 1111 are connected to the first anodes 1151 within the preset range of the camera area 1111, while the number of sub-metal layers 116 is as small as possible. Thus, the forming process of the metal connection layer 116 is reduced.

Specifically, the first anode 1151 and the second anode 1152 corresponding to the red sub-pixel are connected through a first sub-metal layer 1161; the first anode 1151 and the second anode 1152 corresponding to the green sub-pixel are connected through a second sub-metal layer 1161; and the first anode 1151 and the second anode 1152 corresponding to the blue sub-pixel are connected through a third sub-metal layer 1161.

In some embodiments, as shown in FIG. 2, there forms a pixel defined layer 117 on the anode layer 115. The pixel defined layer 117 includes sub-pixel openings, which can expose the first and second anodes 1151, 1152 to accommodate an organic electroluminescent (EL) layer 118. Wherein, the organic electroluminescent layer 118 may include a hole transport layer (HTL), an emitting layer (EML), an electron transport layer (ETL) and so on, which will not be discussed here.

Optionally, there forms a cathode layer 119 and a packaging layer 120 on the organic electroluminescent layer 118 in turn. The cathode layer 119 is used to provide electrons. The packaging layer 120 is used to protect the cathode layer 119 and the organic electroluminescent layer.

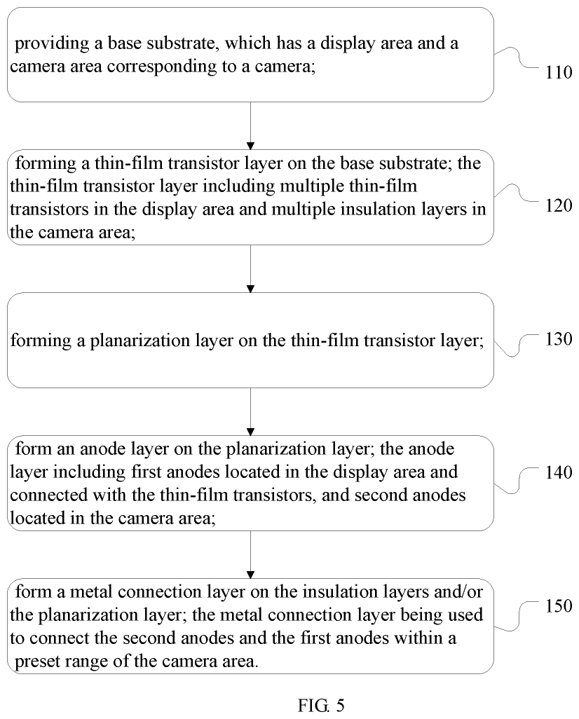

The present application also provides a method for manufacturing the array substrate. Referring to FIGS. 2 to 5, the method includes steps 110 to 150, which are described as follows.

A step 110 is to provide a base substrate 111 having a display area 1112 and a camera area 1111 corresponding to a camera.

A step 120 is to form a thin-film transistor layer 113 on the base substrate 111. The thin-film transistor layer 113 includes multiple thin-film transistors in the display area 1112 and multiple insulation layers in the camera area 1111.

A step 130 is to form a planarization layer 114 on the thin-film transistor layer 113.

A step 140 is to form an anode layer 115 on the planarization layer 114. The anode layer 115 includes first anodes 1151 located in the display area 1112 and connected with the thin-film transistors, and second anodes 1152 located in the camera area 1111.

A step 150 is to form a metal connection layer 116 on the insulation layers and/or the planarization layer 114. The metal connection layer 116 can connect the second anodes 1152 and the first anodes 1151 within a preset range of the camera area 1111.

Understandably, for the array substrate 11 manufactured by the above-mentioned method, when a voltage is applied to the thin-film transistor within the preset range of the camera area 1111, pixel units in the camera area 1111 can display the color to hide the camera under the array substrate 11. Moreover, because the camera area 1111 of the base substrate 111 is not provided with thin-film transistors and signal lines, a light transmittance of the camera area 1111 is increased, and more external light can enter into the camera through the camera area 1111 of the base substrate 111, thereby improving the image effect of the camera.

It should be noted that the sequence of the steps in the above method is not limited, which can be determined according to the structure of the array substrate 11. In the step 150, the insulation layers include a gate insulation layer 1134, an inter-level dielectric layer 1135 and so on. The metal connection layer 116 may be formed on the gate insulation layer 1134, or formed on the inter-level dielectric layer 1135. Moreover, the thin-film transistor layer 113, the planarization layer 114, the anode layer 115 and the metal connection layer 116 can be formed by solution method, vapor deposition method, etc., which will not be discussed here.

In some embodiments, the method for manufacturing the array substrate further includes steps 160 to 190, which are described as follows.

A step 160 is to form a pixel defined layer 117 on the anode layer 115. The pixel defined layer 117 includes sub-pixel openings exposing the first and second anodes 1151, 1152.

A step 170 is to form an organic electroluminescent layer 118 on the pixel defined layer 117. The organic electroluminescent layer 118 may include a hole transport layer, an emitting layer, an electron transport layer etc.

A step 180 is to form a cathode layer 119 on the organic electroluminescent layer 118.

A step 190 is to form a packaging layer 120 on the cathode layer 119.

Wherein, the pixel defined layer 117, the organic electroluminescent layer 118, the cathode layer 119 and the packaging layer 120 may be formed by solution method, vapor deposition method, etc.

In some embodiments, before forming the thin-film transistor layer 113 on the base substrate 111, the method further includes a step of forming a buffer layer 112 on the base substrate 111. The buffer layer 112 is located between the base substrate 111 and the thin-film transistor layer 113.

The present application also provides a display device, including the above array substrate, or the array substrate manufactured by the above method. The specific structure of the array substrate refers to the above embodiments. Because the display device of the application employs all the technical schemes of all the above embodiments, the display device has all the beneficial effects brought about by the technical schemes of the above embodiments, which will not be described in detail herein.

Wherein, the display device may be any display device with the above array substrate, such as a flexible display device, a micro-light-emitting diode display device, an organic light-emitting diode display device, etc. There is no restriction here.

In the above-mentioned embodiments, the description of each embodiment has its own emphasis. The part not detailed in one embodiment can be referred to the detailed description for other embodiments above, which will not be repeated here.

When implemented, each of the above units or structures can be implemented as a separate unit, or any combination of them as one or several units. The specific implementation of the above units or structures can be referred to the preceding embodiments of the method, which will not be repeated here.

The specific implementation of each operation can be referred to the preceding embodiments, which will not be repeated here.

The array substrate, the method for manufacturing the same and the display device provided in this application are described in detail above. In this text, specific cases are applied to illustrate the principle and implementation mode of the invention. The above embodiment is only used to help understand the method and the core idea thereof. At the same time, for the technical personnel in the field, according to the idea of the invention, there will be changes in the specific implementation mode and application scope. To sum up, the content of the specification should not be understood as the limitation of the invention.

What is claimed is:

1. An array substrate, wherein, being applied in a display device with a camera; the array substrate including:
a base substrate, having a display area and a camera area corresponding to the camera;
a thin-film transistor layer, being formed on the base substrate; the thin-film transistor layer including thin-film transistors in the display area and multiple insulation layers in the camera area;
a planarization layer, being formed on the thin-film transistor layer;
an anode layer, being formed on the planarization layer; the anode layer including first anodes in the display area and being connected with the thin-film transistors, and second anodes in the camera area; and
a metal connection layer, connecting the second anodes and the first anodes within a preset range of the camera area.

2. The array substrate as claimed in claim 1, wherein the first anode and the second anode corresponding to the same color sub-pixel are connected together by the metal connection layer.

3. The array substrate as claimed in claim 2, wherein the first anodes and the second anodes are arranged on the planarization layer in array; the first anode and the second anode on the same line or the same column are connected together through the metal connection layer.

4. The array substrate as claimed in claim 1, wherein the metal connection layer is formed on the planarization layer.

5. The array substrate as claimed in claim 1, wherein the thin-film transistor includes a gate layer, an active layer and a source-drain layer; the metal connection layer is disposed in the same layer as the gate layer, the active layer and the source-drain layer.

6. The array substrate as claimed in claim 1, wherein the metal connection layer includes multiple sub-metal layers arranged in turn along an up and down direction; the insulation layers or the planarization layer are formed between adjacent two sub-metal layers; the first anode and the second anode corresponding to the same color sub-pixel are connected together by the same sub-metal layer.

7. The array substrate as claimed in claim 6, wherein the insulation layers includes a gate insulation layer and an inter-level dielectric layer; the number of the sub-metal layers is three; the three sub-metal layers are formed on the gate insulation layer, the inter-level dielectric layer and the planarization layer, respectively.

8. The array substrate as claimed in claim 1, wherein a pixel defined layer is formed on the anode layer, and includes sub-pixel openings exposing the first and second anodes and accommodating an organic electroluminescent layer.

9. The array substrate as claimed in claim 1, wherein the array substrate further includes a buffer layer, which is located between the base substrate and the thin-film transistor layer.

10. A method for manufacturing an array substrate, wherein, including:
providing a base substrate, which has a display area and a camera area corresponding to a camera;
forming a thin-film transistor layer on the base substrate; the thin-film transistor layer including multiple thin-film transistors in the display area and multiple insulation layers in the camera area;
forming a planarization layer on the thin-film transistor layer;
form an anode layer on the planarization layer; the anode layer including first anodes located in the display area and connected with the thin-film transistors, and second anodes located in the camera area; and
form a metal connection layer on the insulation layers and/or the planarization layer; the metal connection layer being used to connect the second anodes and the first anodes within a preset range of the camera area.

11. The method for manufacturing the array substrate as claimed in claim 10, wherein the method further includes:
forming a pixel defined layer on the anode layer; the pixel defined layer including sub-pixel openings exposing the first and second anodes;
forming an organic electroluminescent layer on the pixel defined layer; the organic electroluminescent layer including a hole transport layer, an emitting layer, an electron transport layer; and
forming a cathode layer on the organic electroluminescent layer.

12. A display device, wherein, including a camera and an array substrate; the array substrate comprising:
a base substrate, having a display area and a camera area corresponding to the camera;
a thin-film transistor layer, being formed on the base substrate; the thin-film transistor layer including thin-film transistors in the display area and multiple insulation layers in the camera area;
a planarization layer, being formed on the thin-film transistor layer;
an anode layer, being formed on the planarization layer; the anode layer including first anodes in the display area and being connected with the thin-film transistors, and second anodes in the camera area; and
a metal connection layer, connecting the second anodes and the first anodes within a preset range of the camera area.

13. The display device as claimed in claim 12, wherein the first anode and the second anode corresponding to the same color sub-pixel are connected together by the metal connection layer.

14. The display device as claimed in claim 13, wherein the first anodes and the second anodes are arranged on the planarization layer in array; the first anode and the second anode on the same line or the same column are connected together through the metal connection layer.

15. The display device as claimed in claim 12, wherein the metal connection layer is formed on the planarization layer.

16. The display device as claimed in claim 12, wherein the thin-film transistor includes a gate layer, an active layer and a source-drain layer; the metal connection layer is disposed in the same layer as the gate layer, the active layer and the source-drain layer.

17. The display device as claimed in claim 12, wherein the metal connection layer includes multiple sub-metal layers arranged in turn along an up and down direction; the insulation layers or the planarization layer are formed between adjacent two sub-metal layers; the first anode and the second anode corresponding to the same color sub-pixel are connected together by the same sub-metal layer.

18. The display device as claimed in claim 17, wherein the insulation layers includes a gate insulation layer and an inter-level dielectric layer; the number of the sub-metal layers is three; the three sub-metal layers are formed on the gate insulation layer, the inter-level dielectric layer and the planarization layer, respectively.

19. The display device as claimed in claim 12, wherein a pixel defined layer is formed on the anode layer, and includes sub-pixel openings exposing the first and second anodes and accommodating an organic electroluminescent layer.

20. The display device as claimed in claim 12, wherein the array substrate further includes a buffer layer, which is located between the base substrate and the thin-film transistor layer.
